(19) United States
(12) Patent Application Publication
(10) Pub. No.: US 2026/0255926 A1
(43) Pub. Date: Aug. 27, 2026

(54) SUBSTRATE HOLDING DEVICE, SUBSTRATE MANUFACTURING APPARATUS, AND SUBSTRATE MANUFACTURING METHOD

(71) Applicant: EBARA CORPORATION, Tokyo (JP)

(72) Inventors: Masayuki SATAKE, Tokyo (JP); Masayuki NAKANISHI, Tokyo (JP)

(21) Appl. No.: 18/880,907

(22) PCT Filed: Jun. 15, 2023
(86) PCT No.: PCT/JP2023/022255

§ 371 Date: Oct. 27, 2025

(30) Foreign Application Priority Data
Jul. 13, 2022 (JP) 2022-112217

(51) Int. Cl. H10P 72/76; H10P 10/00; H10P 72/00

(52) U.S. Cl. CPC H10P 72/7608; H10P 10/128; H10P 72/0438

(57) ABSTRACT

The application relates to a substrate holding device, a substrate manufacturing apparatus, and a substrate manufacturing method. The substrate holding device includes a holding roller and a fluid blowing device configured to blow a pressurized fluid onto a bevel portion held by the holding roller.

### TECHNICAL FIELD

The present invention relates to a substrate holding device, a substrate manufacturing apparatus, and a substrate manufacturing method.

### BACKGROUND ART

In three-dimensional packaging technology for laminating and integrating substrates, device surfaces of the substrates are bonded together, and then a non-device surface of one of the substrates is ground. The substrate has a rounded or chamfered shape (bevel portion) on a peripheral portion of the substrate.

Therefore, when a bevel portion becomes thin due to grinding, a sharp edge portion (knife edge portion) is formed, which may result in defects such as cracks and chips. Therefore, in a bevel fill technology, a gap between the bevel portions in a laminated substrate is filled with a filler, which supports the knife edge portion and prevents an occurrence of defects.

### CITATION LIST

### Patent Literature

Patent document 1: Japanese laid-open patent publication No. 2022-38834

### SUMMARY OF INVENTION

### Technical Problem

However, if air bubbles are mixed in the filler applied to the gap between the bevel portion, the air bubbles (i.e., cavities) inside the filler may cause defects in the substrate. More specifically, when a grinding load is applied to the knife edge portion, the filler may not be able to fully support the knife edge portion in the cavity portion, and as a result, defects such as cracks and chips may occur in the substrate. Therefore, it is important to remove the air bubbles mixed in the filler in order to prevent defects from occurring in the substrate.

In addition, it is also important to remove foreign matter (e.g., liquid, particles, etc.) attached to the bevel portion of the substrate from a viewpoint of preventing defects from occurring in the substrate. Not only in a case of the laminated substrate described above, but also in a case of a general substrate (i.e., a substrate not having a laminate), if the foreign matter is attached to the bevel portion of the substrate, the substrate may be contaminated, which may result in defects in the substrate.

Thus, keeping the bevel portion of the substrate clean, including removing the air bubbles mixed in the filler and removing the foreign matter from the bevel portion, is important from a standpoint of preventing defects from occurring in the substrate.

Therefore, the present invention provides a substrate holding device, a substrate manufacturing apparatus, and a substrate manufacturing method that are capable of preventing defects from occurring in a substrate.

### Solution to Problem

In an embodiment, there is provided a substrate holding device comprising: a holding roller configured to hold a bevel portion of a substrate while rotating the substrate; and a fluid blowing device configured to be coupled to the holding roller and blow a pressurized fluid onto the bevel portion held by the holding roller.

In an embodiment, the fluid blowing device comprises: a fluid supply line configured to be coupled to a blowing port formed in the holding roller; and a fluid supply device configured to be connected to the fluid supply line.

In an embodiment, comprising a clamp device configured to move a first clamp portion and a second clamp portion of the holding roller closer to or farther away from each other, the first clamp portion and the second clamp portion being configured to clamp the bevel portion.

In an embodiment, comprising a roller moving device configured to move the holding roller between a contact position in contact with the bevel portion and a separation position away from the bevel portion.

In an embodiment, there is provided a substrate manufacturing apparatus for manufacturing a laminated substrate formed by bonding a first substrate and a second substrate, comprising: a holding roller configured to hold the laminated substrate and rotate the laminated substrate; a fluid blowing device configured to be coupled to the holding roller and blow a pressurized fluid into a gap in the laminated substrate held by the holding roller; and a coating device configured to apply a filler to the gap.

In an embodiment, the fluid blowing device comprises: a fluid supply line configured to be coupled to a blowing port formed in the holding roller; and a fluid supply device configured to be connected to the fluid supply line.

In an embodiment, comprising a clamp device configured to move a first clamp portion and a second clamp portion of the holding roller closer to or farther away from each other, the first clamp portion and the second clamp portion being configured to clamp the bevel portion of the laminated substrate.

In an embodiment, comprising a roller moving device configured to move the holding roller between a contact position in contact with the bevel portion of the laminated substrate and a separation position away from the bevel portion.

In an embodiment, the fluid blowing device comprises a heater configured to heat a fluid to blow onto the bevel portion of the laminated substrate.

In an embodiment, the coating device comprises an injection nozzle configured to inject a pressurized fluid onto the filler supplied to a supply nozzle configured to supply the filler toward the gap.

In an embodiment, there is provided a substrate manufacturing method for manufacturing a laminated substrate formed by bonding a first substrate and a second substrate, comprising: a step of rotating the laminated substrate while holding the laminated substrate by a holding roller; a step of applying a filler to a gap in the laminated substrate; and a step of blowing a pressurized fluid into the gap and being coupled to the holding roller.

In an embodiment, the step of blowing the pressurized fluid comprises a step of blowing the pressurized fluid from a blowing port formed in the holding roller.

In an embodiment, comprising a step of moving a first clamp portion and a second clamp portion of the holding roller closer to or farther away from each other, the first clamp portion and the second clamp portion being configured to clamp a bevel portion of the laminated substrate.

In an embodiment, comprising a step of moving the holding roller between a contact position in contact with a bevel portion of the laminated substrate and a separation position away from the bevel portion.

In an embodiment, comprising a step of heating a fluid to blow onto a bevel portion of the laminated substrate.

In an embodiment, comprising a step of injecting a pressurized fluid onto a filler supplied to a supply nozzle configured to supply the filler toward the gap.

### Advantageous Effects of Invention

The fluid blowing device can keep the bevel portion of the substrate clean by blowing the pressurized fluid onto the bevel portion of the substrate, thereby preventing defects from occurring on the substrate.

### BRIEF DESCRIPTION OF DRAWINGS

FIG. 1A is an enlarged cross-sectional view showing a peripheral portion of a wafer, which is an example of a substrate;

FIG. 1B is an enlarged cross-sectional view showing a peripheral portion of a wafer, which is an example of a substrate;

FIG. 2A is a schematic view showing an example of a laminated wafer obtained by bonding two wafers;

FIG. 2B is a schematic view showing the laminated wafer after a second wafer shown in FIG. 2A has been ground (thinned);

FIG. 3 is a view showing an embodiment of a substrate manufacturing apparatus;

FIG. 4 is a view showing one embodiment of a substrate holding device;

FIG. 5A is a view showing a state in which a pressurized fluid is ejected into a gap in the laminated wafer;

FIG. 5B is a view showing a state in which the pressurized fluid is ejected into the gap in the laminated wafer;

FIG. 6 is a view showing a lamination process of laminated wafer;

FIG. 7 is a view showing a clamp device that clamps the laminated wafer with the holding roller;

FIG. 8 is a view showing another embodiment of the fluid blowing device; and

FIG. 9 is a view showing another embodiment of the coating device.

### DESCRIPTION OF EMBODIMENTS

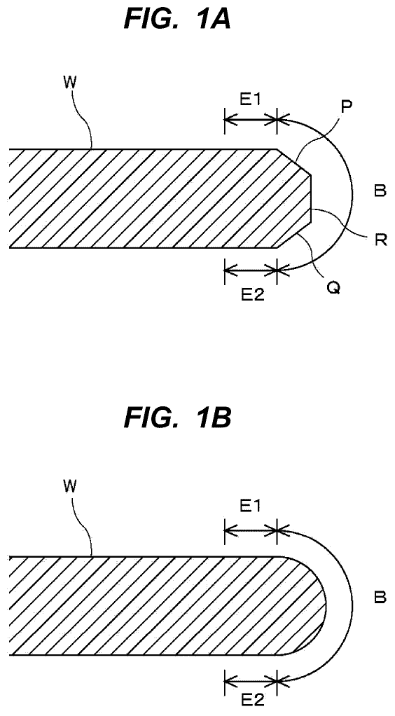

FIGS. 1A and 1B are enlarged cross-sectional views showing a peripheral portion of a wafer, which is an example of a substrate. More specifically, FIG. 1A is a cross-sectional view of a so-called straight type wafer, and FIG. 1B is a cross-sectional view of a so-called round type wafer. In the wafer W of FIG. 1A, a bevel portion is an outermost peripheral surface (indicated by the symbol B) of the wafer W, which is composed of an upper inclined portion (upper bevel portion) P, a lower inclined portion (lower bevel portion) Q, and a side portion (apex) R.

In the wafer W of FIG. 1B, the bevel portion is a portion (indicated by the symbol B) having a curved cross section that constitutes the outermost peripheral surface of the wafer W. A top edge portion E1 is a flat portion that is located radially inward from the bevel portion B and radially outward from a region D where devices are formed. The top edge portion E1 may also include a region where devices are formed. A bottom edge portion E2 is a flat portion that is located on an opposite side to the top edge portion E1 and radially inward from the bevel portion B. The top edge portion E1 and the bottom edge portion E2 are sometimes collectively referred to as near edge portions.

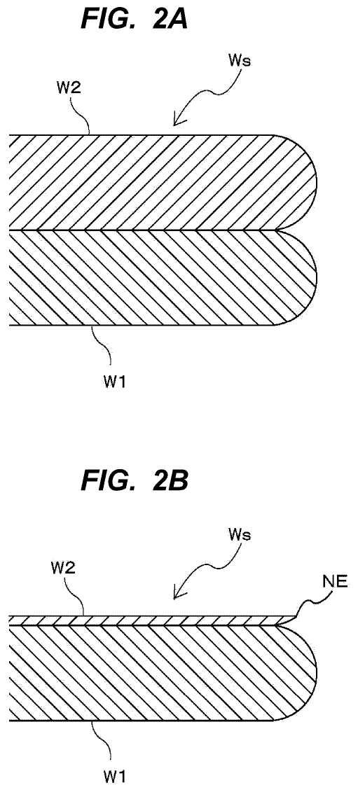

FIG. 2A is a schematic view showing an example of a laminated wafer obtained by bonding two wafers, and FIG. 2B is a schematic view showing the laminated wafer after the second wafer shown in FIG. 2A has been ground (thinned). A laminated wafer Ws shown in FIG. 2A is manufactured by bonding a rounded first wafer W1 and a rounded second wafer W2 shown in FIG. 1B.

As shown in FIG. 2B, when the second wafer W2 is thinned, a knife edge portion NE is formed on the peripheral portion of the second wafer W2. This knife edge portion NE is easily chipped by physical contact, which may result in defects such as cracks and chips in the laminated wafer Ws. Therefore, the knife edge portion NE is effectively protected by applying a filler between the first wafer W1 and the second wafer W2 of the laminated wafer Ws and curing the filler.

However, if air bubbles are mixed in the filler, there is a risk of defects such as cracks and chips occurring in the knife edge portion NE. It is important to remove the air bubbles mixed in the filler in order to prevent defects from occurring in the laminated wafer Ws.

As described above, it is also important to remove foreign matter (e.g., liquid, particles, etc.) adhering to the bevel portion B of the wafer W in order to prevent defects from occurring in the wafer W. Hereinafter, a substrate manufacturing apparatus capable of preventing defects from occurring in the wafer W (including laminated wafer Ws) will be described with reference to the drawings.

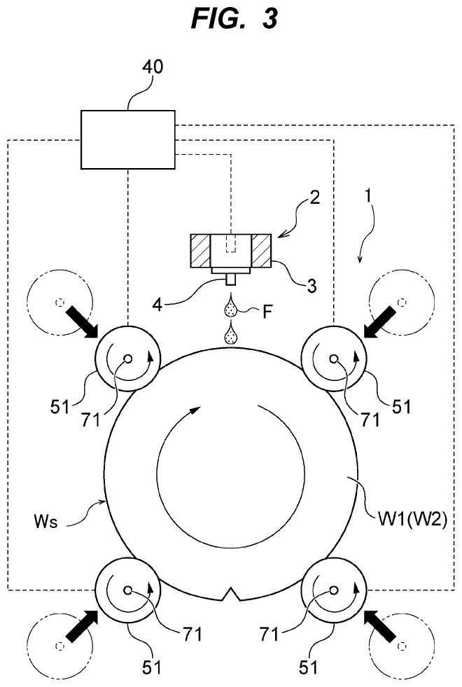

FIG. 3 is a view showing an embodiment of a substrate manufacturing apparatus. The substrate manufacturing apparatus is an apparatus for manufacturing (i.e., processing) the laminated wafer Ws formed by bonding the first wafer W1 and the second wafer W2 together. Therefore, the substrate manufacturing apparatus may be called a substrate processing apparatus.

The substrate manufacturing apparatus includes a substrate holding device 1 that holds the laminated wafer Ws, and a coating device 2 that applies a filler F to the gap between the bevel portion B of the first wafer W1 and the bevel portion B of the second wafer W2 (i.e., the gap in the laminated wafer Ws).

The coating device 2 is disposed above the laminated wafer Ws held in a vertical direction. More specifically, the laminated wafer Ws is held with its plane surface perpendicular to a horizontal plane. In other words, the laminated wafer Ws is held in an upright position. The coating device 2 includes a supply nozzle 4 that supplies the filler F toward the gap in the laminated wafer Ws, and a support arm 3 that supports the supply nozzle 4.

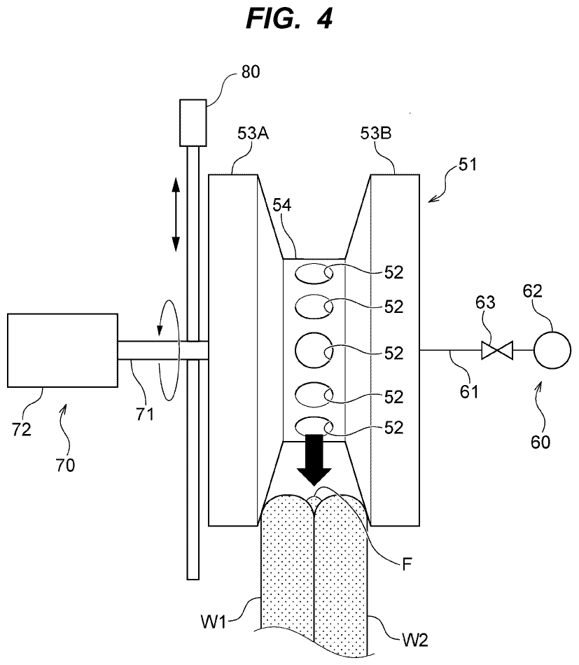

FIG. 4 is a view showing one embodiment of a substrate holding device. As shown in FIG. 4, the substrate holding device 1 includes a holding roller 51 that rotates the laminated wafer Ws while holding the peripheral portion of the laminated wafer Ws, and a fluid blowing device 60 that is coupled to the holding roller 51 and blows a pressurized fluid onto the peripheral portion of the laminated wafer Ws held by the holding roller 51.

The pressurized fluid is a fluid to which kinetic energy has been imparted. In this embodiment, the pressurized fluid refers to a gas pressurized to a pressure required to remove the air bubbles from the filler F.

By holding the peripheral portion of the laminated wafer Ws with the holding rollers 51, it is possible to prevent the foreign matter from adhering to a surface (and back surface) of the laminated wafer Ws. In the embodiment shown in FIG. 4, the substrate holding device 1 includes four holding rollers 51, but the number of holding rollers 51 is not limited to this embodiment as long as the substrate holding device 1 can hold the laminated wafer Ws. In this embodiment, the substrate holding device 1 holds the laminated wafer Ws in the vertical direction, but the substrate holding device 1 may hold the laminated wafer Ws in a horizontal direction.

As shown in FIG. 4, each holding roller 51 includes a first clamp portion 53A and a second clamp portion 53B that clamp the peripheral portion of the laminated wafer Ws, and a shaft portion 54 arranged between the first clamp portion 53A and the second clamp portion 53B.

The substrate holding device 1 includes a roller rotating device 70 that rotates the holding roller 51. The roller rotating device 70 includes a connection rod 71 connected to the holding roller 51 (more specifically, the first clamp portion 53A (or the second clamp portion 53B)), and a motor 72 that rotates the connection rod 71.

The fluid blowing device 60 includes a fluid supply line 61 coupled to a blowing port 52 formed on an outer circumferential surface of the shaft portion 54, a fluid supply device 62 connected to the fluid supply line 61, and an on-off valve 63 for opening and closing the fluid supply line 61. In the embodiment shown in FIG. 4, a plurality of blowing ports 52 are formed, but at least one blowing port 52 may be formed. The blowing port 52 is formed on the outer circumferential surface of the shaft portion 54 of the holding roller 51. Therefore, when the holding roller 51 holds the laminated wafer Ws, the blowing port 52 faces the gap in the laminated wafer Ws.

As long as the pressurized fluid can be supplied to the gap in the laminated wafer Ws, the blowing port 52 does not necessarily have to be formed in the shaft portion 54. In one embodiment, the fluid blowing device 60 may include the blowing port 52 formed in at least one of the clamp portions 53A and 53B.

The substrate manufacturing apparatus includes a control device 40 (see FIG. 3) that controls an operation of the roller rotating device 70. The control device 40 is electrically connected to the roller rotating device 70 and configured to rotate the holding roller 51 via the roller rotating device 70. When the holding roller 51 rotates with the laminated wafer Ws held by the holding roller 51, the laminated wafer Ws rotates together with the holding roller 51.

The control device 40 is configured to control an operation of the fluid blowing device 60. When the control device 40 drives the fluid supply device 62 with the on-off valve 63 open, the pressurized fluid is blown out from the blowing port 52 through the fluid supply line 61.

The control device 40 is configured to control an operation of the coating device 2. The control device 40 operates the roller rotating device 70 to rotate the laminated wafer Ws via the holding roller 51, and operates the coating device 2 to supply the filler F from above the laminated wafer Ws via the supply nozzle 4. By supplying the filler F while rotating the laminated wafer Ws, the gap in the laminated wafer Ws is filled with the filler F over an entire circumference of the laminated wafer Ws.

In the embodiment shown in FIGS. 3 and 4, the substrate holding device 1 includes a roller moving device 80 that moves the holding roller 51 between a contact position where the holding roller 51 contacts the peripheral portion of the laminated wafer Ws and a separation position where the holding roller 51 is separated from the peripheral portion of the laminated wafer Ws.

In one embodiment, the roller moving device 80 may include a linear actuator coupled to the roller rotating device 70. The roller moving device 80 is configured to move the holding roller 51 via the roller rotating device 70. Components of the roller moving device 80 are not particularly limited as long as they can move the holding roller 51 between the contact position and the separation position. In one embodiment, the roller moving device 80 may be a combination of a ball screw and a linear guide.

When the laminated wafer Ws transported to the substrate holding device 1 by a transport device (not shown) are held by the holding rollers 51, the roller moving device 80 moves the holding rollers 51 to the contact position. Thereafter, the fluid blowing device 60 removes the air bubbles from the filler F applied to the gap in the laminated wafer Ws. After removing the air bubbles, the roller moving device 80 moves the holding rollers 51 to the separation position when separating the laminated wafer Ws from the holding rollers 51. Thereafter, the laminated wafer Ws is transported to a post-processing module by a transport device (not shown).

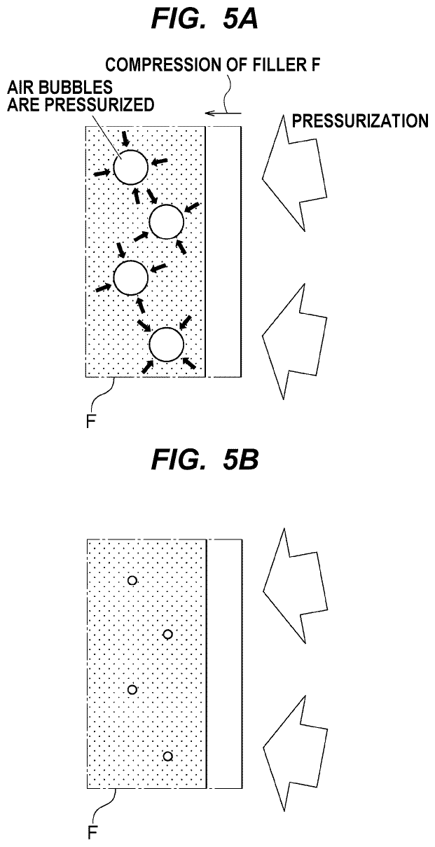

FIGS. 5A and 5B are views showing a state in which the pressurized fluid is ejected into the gap in the laminated wafer. As shown in FIG. 5A, the pressurized fluid is ejected from the holding roller 51 onto the filler F on the gap in the laminated wafer Ws, whereby the filler F is compressed.

As shown in FIG. 5B, the air bubbles mixed in the filler F are compressed together with the filler F, and eventually become small enough that they do not adversely affect the knife edge portion NE. A size of the air bubbles reduced by the ejection of the pressurized fluid does not return to their original size. In this manner, the fluid blowing device 60 can remove the air bubbles from the filler F applied to the gap in the laminated wafer Ws.

According to the embodiment, the fluid blowing device 60 can remove the air bubbles from the filler F applied to the gap in the laminated wafer Ws. Therefore, the substrate manufacturing apparatus can prevent defects such as cracks and chips from occurring in the knife edge portion NE due to the air bubbles mixed in the filler F.

According to the embodiment, the fluid blowing device 60 can remove foreign matter (e.g., liquid, particles, etc.) adhering to the bevel portion B of the wafer W, and can keep the bevel portion B clean. Therefore, the substrate manufacturing apparatus can prevent defects from occurring in the wafer W due to foreign matter adhering to the bevel portion B of the wafer W.

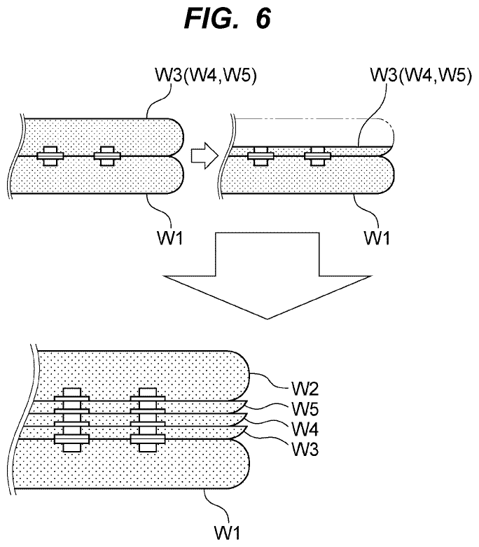

FIG. 6 is a view showing a lamination process of laminated wafer. As shown in FIG. 6, in a state where the wafer W1 and the wafer W3 (W4, W5) are bonded together, the back surface of the wafer W3 (W4, W5) is ground (thinned) to perform a grinding process. By repeating such a grinding process and laminating the wafer W3 (W4, W5) on the wafer W1, the thickness of the laminated wafer Ws in the thickness direction increases.

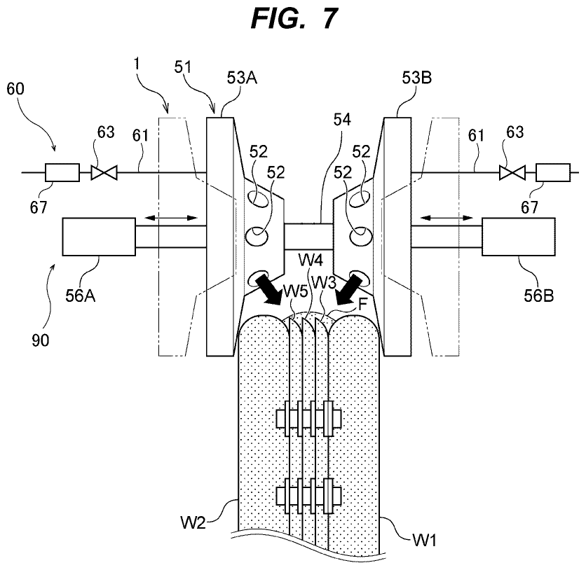

FIG. 7 is a view showing a clamp device that clamps the laminated wafer with the holding roller. In the embodiment shown in FIG. 7, the roller rotating device 70 is omitted. As shown in FIG. 7, the substrate holding device 1 includes a clamp device 90 that moves the first clamp portion 53A and the second clamp portion 53B of the holding roller 51 toward or away from each other. The clamp device 90 includes a first clamp actuator 56A coupled to the first clamp portion 53A and a second clamp actuator 56B coupled to the second clamp portion 53B.

Each of the clamp actuators 56A, 56B is configured to move each of the clamp portions 53A, 53B in an axial direction of the shaft portion 54. Each of the clamp actuators 56A, 56B is, for example, a piston rod. The control device 40 is configured to control an operation of each of the clamp actuators 56A, 56B.

The control device 40 can move the clamp portions 53A and 53B in directions to move closer to or farther away from each other by operating the clamp actuators 56A and 56B, respectively. With this configuration, the clamp device 90 can clamp the laminated wafer Ws having various thicknesses.

In an embodiment shown in FIG. 7, the blowing port 52 is formed on each of the inclined surfaces of the clamp portions 53A and 53B. In one embodiment, the blowing port 52 may be formed on the shaft portion 54. In this embodiment as well, the blowing port 52 faces the gap in the laminated wafer Ws, so that the fluid blowing device 60 can remove the air bubbles from the filler F applied onto the gap in the laminated wafer Ws.

The filler F is known to have a property of being hardened by heating. When using the filler F, in order to effectively protect the knife edge portion NE, it is desirable to remove the air bubbles from the filler F, and then supply high-temperature gas (i.e., a temperature required to harden the filler F) to the filler F to heat the filler F. The temperature required to harden the filler F is, in other words, the hardening temperature.

Therefore, the fluid blowing device 60 may be configured to supply a heated fluid that is heated to a temperature equal to or higher than the curing temperature from at least one of the holding rollers 51. For example, the fluid blowing device 60 may include a heater 67 connected to the fluid supply line 61 (see FIG. 7).

The heated fluid, which is heated to a temperature equal to or higher than the curing temperature as a result of the fluid flowing through the fluid supply line 61 passing through the heater 67, is blown out from the blowing port 52 of the holding roller 51 and cures the filler F applied onto the gap in the laminated wafer Ws. In one embodiment, the pressurized fluid pressurized to a pressure required to remove the air bubbles from the filler F may be heated to a temperature equal to or higher than the curing temperature, and the heated pressurized fluid may be supplied. With this configuration, the fluid blowing device 60 can remove the air bubbles and cure the filler F.

In the embodiment shown in FIG. 3, four holding rollers 51 are arranged. Hereinafter, the holding roller 51 arranged downstream of the coating device 2 in a rotation direction of the laminated wafer Ws and adjacent to the coating device 2 is referred to as the first holding roller 51. The holding roller 51 arranged downstream of the first holding roller 51 in the rotation direction of the laminated wafer Ws and adjacent to the first holding roller 51 is referred to as the second holding roller 51. The holding roller 51 arranged downstream of the second holding roller 51 in the rotation direction of the laminated wafer Ws and adjacent to the second holding roller 51 is referred to as the third holding roller 51. The holding roller 51 arranged downstream of the third holding roller 51 in the rotation direction of the laminated wafer Ws and adjacent to the third holding roller 51 is referred to as the fourth holding roller 51.

In this case, the fluid blowing device 60 supplies unheated pressurized fluid from each of the first and second holding rollers 51 to remove the air bubbles from the filler F, and supplies the heated fluid from the third and fourth holding rollers 51 to harden the filler F from which the air bubbles have been removed. With this configuration, the filler F can be hardened immediately after the air bubbles are removed from the filler F applied to the gap in the laminated wafer Ws. Therefore, the application of the filler F, the removal of the air bubbles, and the hardening of the filler F can be performed in a short time, and as a result, the process time of the laminated wafer Ws can be shortened. In one embodiment, the heated fluid supplied from the third and fourth holding rollers 51 may be pressurized to a pressure required to remove the air bubbles from the filler F.

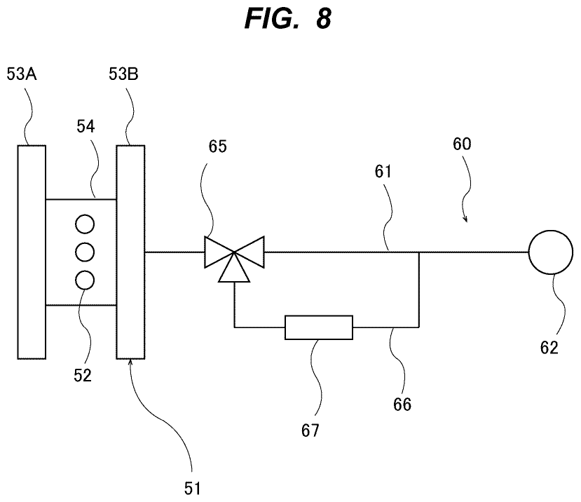

FIG. 8 is a view showing another embodiment of the fluid blowing device. In the embodiment shown in FIG. 8, the fluid blowing device 60 is configured to switch between an unheated pressurized fluid and a heated fluid (pressurized fluid or unpressurized fluid). The fluid blowing device 60 includes a bypass line 66 branched from a fluid supply line 61, a switching valve 65 connected to the fluid supply line 61 and the bypass line 66, and a heater 67 connected to the bypass line 66. The fluid blowing device 60 configured in this manner is connected to at least one of the holding rollers 51.

The fluid blowing device 60 is configured to heat the fluid to be blown onto the peripheral portion of the laminated wafer Ws through the heater 67. The control device 40 is configured to control an operation of the fluid blowing device 60. The control device 40 operates the switching valve 65 to open the fluid supply line 61 and close the bypass line 66. With this operation, the fluid supplied from the fluid supply device 62 is supplied from the blowing port 52 without being heated.

The control device 40 opens the bypass line 66 and closes the upstream side of the fluid supply line 61 (i.e., the fluid supply line 61 between the switching valve 65 and the fluid supply device 62) by switching the switching valve 65. By such an operation, the fluid supplied from the fluid supply device 62 is heated by the heater 67, and the heated pressurized fluid is supplied from the blowing port 52.

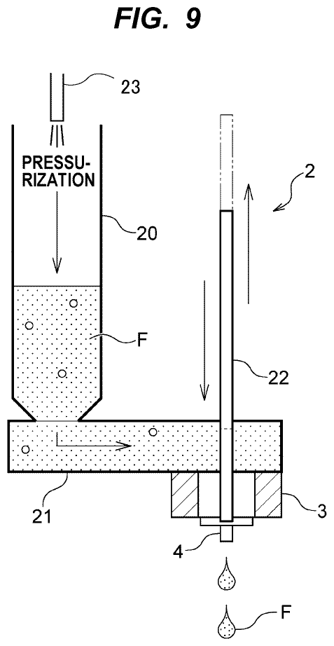

FIG. 9 is a view showing another embodiment of the coating device. As shown in FIG. 9, the coating device 2 may include a syringe body 20 filled with the filler F, an introduction portion 21 that introduces the filler F in the syringe body 20 to the supply nozzle 4 through the support arm 3, a rod 22 that pushes the filler F in the introduction portion 21 to the supply nozzle 4, and an injection nozzle 23 that ejects a pressurized fluid (e.g., nitrogen gas) into the filler in the syringe body 20.

There may be cases where the air bubbles have already been mixed into the filler F in the syringe body 20. Therefore, in the embodiment shown in FIG. 9, the injection nozzle 23 is configured to inject the pressurized fluid into the filler F supplied to the supply nozzle 4 (i.e., the filler F in the syringe body 20) to remove the air bubbles from the filler F before it is applied to the gap in the laminated wafer Ws.

The control device 40 is configured to be able to control an operation of the injection nozzle 23. More specifically, the control device 40 is electrically connected to a fluid supply source (not shown) that supplies the pressurized fluid through the injection nozzle 23. By injecting the pressurized fluid from the injection nozzle 23, the air bubbles mixed in the filler F inside the syringe body 20 are compressed together with the filler F, and eventually become small enough that they do not adversely affect the knife edge portion NE (see FIGS. 5A and 5B).

In the above-described embodiment, an embodiment in which the substrate manufacturing apparatus including the substrate holding device 1 is applied to the laminated wafer Ws has been described, but the substrate manufacturing apparatus according to this embodiment is applicable not only to the laminated wafer Ws but also to a general wafer W (i.e., non-laminated wafer). The laminated wafer Ws in this embodiment correspond to the wafer W, and the peripheral portion of the laminated wafer Ws corresponds to the bevel portion B of the wafer W. Therefore, the bevel portion B of the wafer W refers to the peripheral portion of the laminated wafer Ws.

The above embodiments are described for the purpose of practicing the present invention by a person with ordinary skill in the art to which the invention pertains. Although preferred embodiments have been described in detail above, it should be understood that the present invention is not limited to the illustrated embodiments, but many changes and modifications can be made therein without departing from the appended claims.

### INDUSTRIAL APPLICABILITY

The present invention is applicable to a substrate holding device, a substrate manufacturing apparatus, and a substrate manufacturing method.

### REFERENCE SIGNS LIST

1 substrate holding device
2 coating device
3 support arm
4 supply nozzle
20 syringe body
21 introduction portion
22 rod
23 injection nozzle
40 control device
51 holding roller
52 blowing port
53A first clamp portion
53B second clamp portion
54 shaft portion
56A first clamp portion
56B second clamp portion
60 fluid blowing device
61 fluid supply line
62 fluid supply device
63 on-off valve
65 switching valve
66 bypass line
67 heater
70 roller rotating device
71 connection rod
72 motor
80 roller moving device
90 clamp device

What is claimed is:

1. A substrate holding device comprising:
a holding roller configured to hold a bevel portion of a substrate while rotating the substrate; and
a fluid blowing device configured to be coupled to the holding roller and blow a pressurized fluid onto the bevel portion held by the holding roller.

2. The substrate holding device according to claim 1,
wherein the fluid blowing device comprises:
a fluid supply line configured to be coupled to a blowing port formed in the holding roller; and
a fluid supply device configured to be connected to the fluid supply line.

3. The substrate holding device according to claim 1, comprising a clamp device configured to move a first clamp portion and a second clamp portion of the holding roller closer to or farther away from each other, the first clamp portion and the second clamp portion being configured to clamp the bevel portion.

4. The substrate holding device according to claim 1, comprising a roller moving device configured to move the holding roller between a contact position in contact with the bevel portion and a separation position away from the bevel portion.

5. A substrate manufacturing apparatus for manufacturing a laminated substrate formed by bonding a first substrate and a second substrate, comprising:
a holding roller configured to hold the laminated substrate and rotate the laminated substrate;
a fluid blowing device configured to be coupled to the holding roller and blow a pressurized fluid into a gap in the laminated substrate held by the holding roller; and
a coating device configured to apply a filler to the gap.

6. The substrate manufacturing apparatus according to claim 5,
wherein the fluid blowing device comprises:
a fluid supply line configured to be coupled to a blowing port formed in the holding roller; and
a fluid supply device configured to be connected to the fluid supply line.

7. The substrate manufacturing apparatus according to claim 5, comprising a clamp device configured to move a first clamp portion and a second clamp portion of the holding roller closer to or farther away from each other, the first clamp portion and the second clamp portion being configured to clamp the bevel portion of the laminated substrate.

8. The substrate manufacturing apparatus according to claim 5, comprising a roller moving device configured to move the holding roller between a contact position in contact with the bevel portion of the laminated substrate and a separation position away from the bevel portion.

9. The substrate manufacturing apparatus according to claim 5, wherein the fluid blowing device comprises a heater configured to heat a fluid to blow onto the bevel portion of the laminated substrate.

10. The substrate manufacturing apparatus according to claim 5, wherein the coating device comprises an injection nozzle configured to inject a pressurized fluid onto the filler supplied to a supply nozzle configured to supply the filler toward the gap.

11. A substrate manufacturing method for manufacturing a laminated substrate formed by bonding a first substrate and a second substrate, comprising:
a step of rotating the laminated substrate while holding the laminated substrate by a holding roller;
a step of applying a filler to a gap in the laminated substrate; and
a step of blowing a pressurized fluid by a fluid blowing device configured to blow the pressurized fluid into the gap and that is coupled to the holding roller.

12. The substrate manufacturing method according to claim 11, wherein the step of blowing the pressurized fluid comprises a step of blowing the pressurized fluid from a blowing port formed in the holding roller.

13. The substrate manufacturing method according to claim 11, comprising a step of moving a first clamp portion and a second clamp portion of the holding roller closer to or farther away from each other, the first clamp portion and the second clamp portion being configured to clamp a bevel portion of the laminated substrate.

14. The substrate manufacturing method according to claim 11, comprising a step of moving the holding roller between a contact position in contact with a bevel portion of the laminated substrate and a separation position away from the bevel portion.

15. The substrate manufacturing method according to claim 11, comprising a step of heating a fluid to blow onto a bevel portion of the laminated substrate.

16. The substrate manufacturing method according to claim 11, comprising a step of injecting a pressurized fluid onto a filler supplied to a supply nozzle configured to supply the filler toward the gap.
